(19) United States
(12) Patent Application Publication
(10) Pub. No.: US 2025/0204210 A1
(43) Pub. Date: Jun. 19, 2025

(54) DISPLAY DEVICE

(71) Applicant: Samsung Display Co., LTD., Yongin-si (KR)

(72) Inventors: KAWON PAK, Yongin-si (KR); JUO NAM, Yongin-si (KR); Seung-won PARK, Yongin-si (KR); KYUNGSIG LEE, Yongin-si (KR); Taek Joon LEE, Yongin-si (KR); Seung Hee JANG, Yongin-si (KR); Jae bok CHANG, Yongin-si (KR)

(21) Appl. No.: 18/964,382

(22) Filed: Nov. 30, 2024

(30) Foreign Application Priority Data
Dec. 14, 2023 (KR) 10-2023-0182161

(51) Int. Cl. H10K 59/80; H10K 59/38; H10K 102/00

(52) U.S. Cl. CPC H10K 59/871; H10K 59/38; H10K 2102/331

(57) ABSTRACT

A display device includes a substrate, a transistor disposed on the substrate, a light-emitting element electrically connected to the transistor, a first layer disposed on the light-emitting element, a color conversion layer that contacts the first layer and includes quantum dots. The first layer includes a surface including a first region having hydrophilicity and a second region having hydrophobicity.

This application claims priority to and priority to Korean Patent Application No. 10-2023-0182161, filed on Dec. 14, 2023, and all the benefits accruing therefrom under 35 U.S.C. § 119, the content of which in its entirety is herein incorporated by reference.

### BACKGROUND

### (a) Field

This disclosure relates to a display device.

### (b) Description of the Related Art

The light-emitting element is a device that emits light when an exciton is formed by the combination of a hole supplied from an anode and an electron supplied from a cathode within the light-emitting layer formed between the anode and the cathode, and this exciton stabilizes.

Light-emitting elements have various advantages such as wide viewing angle, fast response speed, thinness, and low power consumption, so the light-emitting elements are widely applied to various electrical and electronic devices such as televisions, monitors, and mobile phones.

Recently, a display device including a color conversion layer is being proposed to implement a highly efficient display device. The color conversion layer may convert incident light into a different color.

### SUMMARY

The embodiments are intended to provide a display device in which the adhesion between the color conversion layer and the first layer on which the color conversion layer is formed is improved and the color conversion layer is patterned without residue.

A display device in an embodiment includes a substrate, a transistor disposed on the substrate, a light-emitting element electrically connected to the transistor, a first layer disposed on the light-emitting element, and a color conversion layer that contacts the first layer and includes quantum dots. The first layer includes a surface including a first region having hydrophilicity and a second region having hydrophobicity.

In an embodiment, the first region may include an acrylate group.

In an embodiment, the second region may include hexamethyldisilazane (“HMDS”).

In an embodiment, the first region and the second region may be randomly arranged.

In an embodiment, the area ratio of the first region to the second region may be 4:6 to 6:4.

In an embodiment, the color conversion layer may be covalently bonded to the first region.

In an embodiment, the color conversion layer may include an acrylate-based photocuring group.

In an embodiment, the acrylate-based photocuring group may form a covalent bond with the first region.

In an embodiment, the light-emitting element may emit blue light.

In an embodiment, the color conversion layer may include a first color conversion layer including red quantum dots, and a second color conversion layer including green quantum dots.

A display device in an embodiment includes a substrate, a transistor disposed on the substrate, a light-emitting element electrically connected to the transistor, a first layer disposed on the light-emitting element, and a color conversion layer in contact with the first layer, and an interface between the first layer and the color conversion layer includes a first region where the first layer and the color conversion layer form a covalent bond.

In an embodiment, the interface between the first layer and the color conversion layer further includes a second region in which the first layer and the color conversion layer do not form a covalent bond, and the first region and the second region are randomly disposed.

In an embodiment, the first layer may be at least one of a glass substrate, an organic insulating layer, and an inorganic insulating layer.

In an embodiment, the first region may be surface treated with a first compound represented by Formula 1 or Formula 2 below.

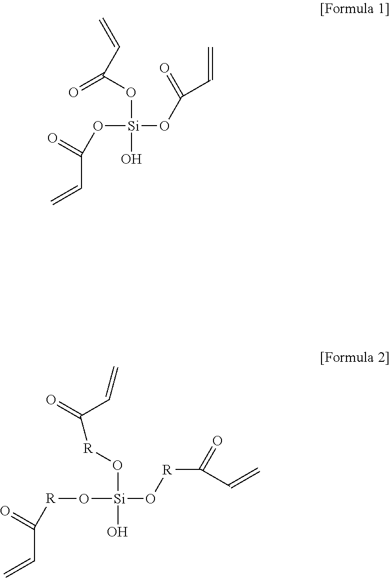

In an embodiment, in Formula 2, R denotes an alkyl group having 1 carbon atom to 20 carbon atoms.

In an embodiment, the second region may be surface treated with a second compound represented by the following Formula 3.

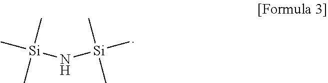

In an embodiment, the area ratio of the first region to the second region may be 4:6 to 6:4.

In an embodiment, the color conversion layer may include an acrylate-based photocuring group.

In an embodiment, the acrylate-based photocuring group may form a covalent bond with the first region.

In an embodiment, the light-emitting element may emit blue light.

In an embodiment, the color conversion layer may include a first color conversion layer including red quantum dots, and a second color conversion layer including green quantum dots.

By embodiments, the adhesion between the color conversion layer and the first layer on which the color conversion layer is formed is improved, and a patterned color conversion layer without residue may be provided, so the reliability of the display device may be improved.

### BRIEF DESCRIPTION OF THE DRAWINGS

The above and other exemplary embodiments, advantages and features of this disclosure will become more apparent by describing in further detail exemplary embodiments thereof with reference to the accompanying drawings, in which:

FIG. 1 is a diagram showing an embodiment of a first layer surface treated.

FIGS. 2 to 4 each show an embodiment of a first layer surface-treated according to a manufacturing process.

FIG. 5 is an exploded perspective view of an embodiment of a display device.

FIG. 6 is a cross-sectional view of an embodiment of a display panel.

FIG. 7 is a cross-sectional view of an embodiment of a display panel.

FIG. 8 is an image showing an embodiment of the contact angle of the first layer surface treated.

FIGS. 9 and 10 are images showing a comparative example of the contact angle of the first layer surface treated.

FIG. 11 is an image of patterning with a photosensitive resin composition on the first layer surface-treated according to an example.

FIG. 12 is an image of a comparative example of patterning with a photosensitive resin composition on the first layer surface-treated.

FIGS. 13 to 15 are tables showing images according to examples and comparative examples.

### DETAILED DESCRIPTION

Hereinafter, with reference to the attached drawings, various embodiments of the invention will be described in detail so that those skilled in the art may easily implement the invention.

Embodiments of the disclosure may be implemented in many different forms and is not limited to the embodiments described herein.

In order to clearly explain the invention, parts that are not relevant to the description are omitted, and identical or similar components are assigned the same reference numerals throughout the specification.

In addition, the size and thickness of each component shown in the drawings are arbitrarily shown for convenience of explanation, so the invention is not necessarily limited to that which is shown.

In the drawings, the thickness is enlarged to clearly express various layers and regions.

And in the drawings, for convenience of explanation, the thicknesses of some layers and regions are exaggerated.

Additionally, when a part of a layer, membrane, region or plate is said to be “above” or “on” another part, this includes not only cases where it is “directly above” another part, but also cases where there is another part in between.

Conversely, when a part is said to be “right on top” of another part, it means that there is no other part in between.

In addition, being “above” or “on” a reference part means being disposed above or below the reference part, and does not necessarily mean being disposed “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “in a plan view,” this means when the target portion is viewed from above, and when reference is made to “in a cross-section,” this means when a cross-section of the target portion is cut vertically and viewed from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

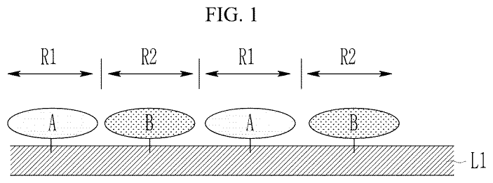

Hereinafter, the interface between the first layer and the color conversion layer in an embodiment will be illustrated with reference to FIGS. 1 to 4.

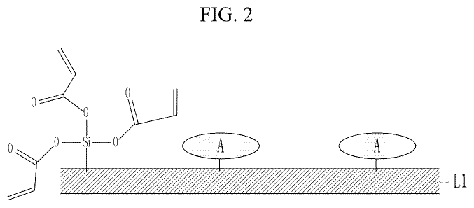

FIG. 1 is a diagram showing an embodiment of a first layer surface-treated, and FIGS. 2 to 4 are diagrams showing an embodiment of a first layer surface-treated according to a manufacturing process.

Referring to FIG. 1, a display device in an embodiment may include a first layer L1.

Depending on the embodiment, the first layer L1 may be a glass substrate, an organic insulating layer, or an inorganic insulating layer.

The first layer L1 in an embodiment may be a layer in which a color conversion layer, which will be described later, is formed.

The first layer L1 may include a first region R1 and a second region R2 as shown in FIG. 1.

The first region R1 and the second region R2 may be randomly arranged.

The ratio (also referred to as an area ratio) of the area occupied by the first region R1 to the area occupied by the second region R2 may be 4:6 to 6:4.

The first region R1 may be a region whose surface has been treated with the first compound (A) including an acrylate group.

Specifically, the first region R1 may be a region surface-treated with the first compound (A) represented by Formula 1 or Formula 2 below.

The first region R1 may have hydrophilicity due to the first compound (A) represented by Formula 1 to Formula 2.

Specifically, the first compound (A) represented by Formula 1 or Formula 2 may be bound to a surface of the first layer L1 as shown in FIG. 2.

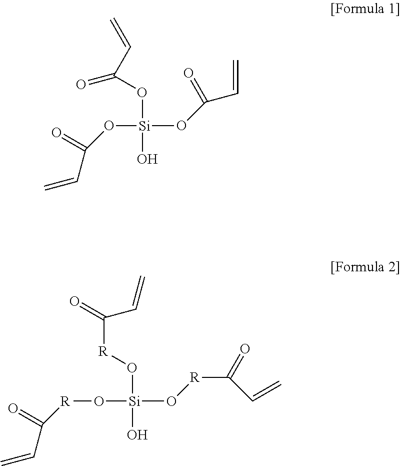

In Formula 2, R denotes an alkyl group having 1 carbon atom to 20 carbon atoms.

The second region R2 may be a region whose surface has been treated with the second compound (B).

The second region R2 may be a region surface-treated with the second compound (B) represented by the following Formula 3.

The second region R2 may exhibit hydrophobicity due to the second compound (B) represented by Formula 3.

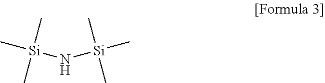

The color conversion layer in an embodiment may be formed on the first layer L1 that has undergone surface treatment, as shown in FIG. 1.

The color conversion layer includes or consists of a photosensitive resin composition, and may be formed through a photocuring process, an exposure process, and a developing process.

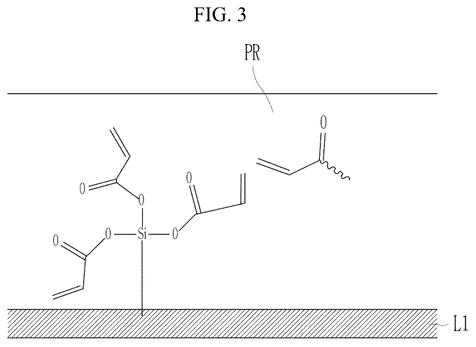

The photosensitive resin composition PR for forming a color conversion layer in an embodiment may include a photocuring group as shown in FIG. 3.

The photocuring group may be an acrylate-based photocuring group.

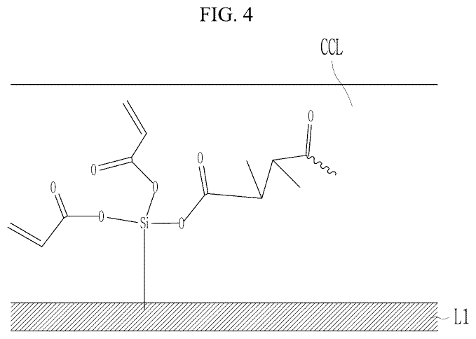

The acrylate-based photocuring group may combine with the first compound represented by Formula 1 and Formula 2 formed in the first region R1 in the exposure process as shown in FIG. 4.

Therefore, the color conversion layer CCL in an embodiment may be covalently bonded to the first region R1 as shown in FIG. 4.

In the first region R1, the first layer L1 and the color conversion layer CCL may form a covalent bond.

The second region R2 has hydrophobicity, and the color conversion layer disposed on the second region R2 is not directly bonded to the second region R2. In an embodiment, the second region R2 includes hexamethyldisilazane (“HMDS”).

In the second region R2, the first layer L1 and the color conversion layer do not form a covalent bond.

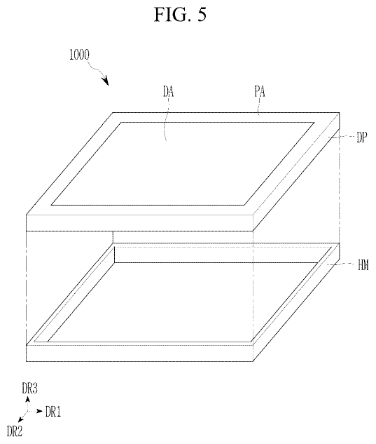

Hereinafter, a display device in an embodiment will be described with reference to FIGS. 5 to 7.

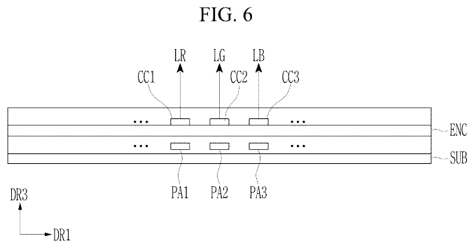

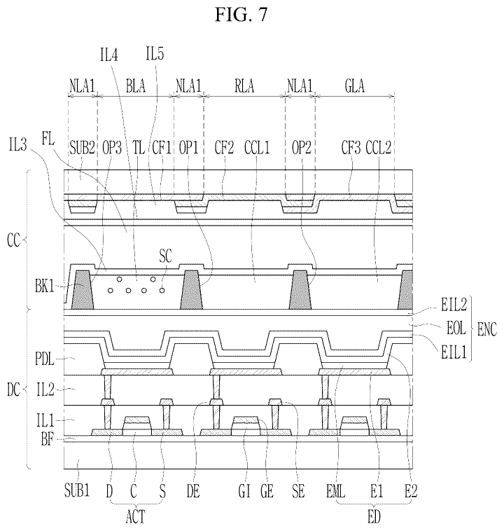

FIG. 5 is an exploded perspective view of an embodiment of a display device, FIG. 6 is a cross-sectional view of an embodiment of a display panel, and FIG. 7 is a cross-sectional view of an embodiment of a display panel.

Referring to FIG. 5, the display device 1000 in an embodiment may include a display panel DP and a housing HM.

A side of the display panel DP on which the image is displayed is parallel to the side defined by the first direction DR1 and the second direction DR2.

The third direction DR3 indicates the normal direction of one side on which the image is displayed, that is, the thickness direction of the display panel DP.

The front (or upper) and back (or lower) surfaces of each member are separated by the third direction DR3.

However, the directions indicated by the first to third directions DR1, DR2, and DR3 are relative concepts and may be converted to other directions.

The display panel DP may be a flat rigid display panel, but is not limited thereto and may be a flexible display panel.

The display panel DP may include or consist of an organic light-emitting display panel.

However, the type of display panel DP is not limited to this and may include or consist of various types of panels.

In an embodiment, the display panel DP may include or consist of a liquid crystal display panel, an electrophoretic display panel, an electrowetting display panel, etc., for example.

Additionally, the display panel DP may include or consist of a next-generation display panel such as a micro light-emitting diode (“LED”) display panel, a quantum dot LED display panel, or a quantum dot organic LED display panel.

Micro LED display panels are made up of LED s measuring 10 micrometers to 100 micrometers to form each pixel.

These micro LED display panels have the following advantages. The micro LED display panels use inorganic materials, the backlight may be omitted, the response speed is relatively fast, relatively high brightness may be achieved with relatively low power, and micro LED display panels do not break when bent.

Quantum dot LED display panels are made by attaching a layer including quantum dots or forming them with a material including quantum dots.

Quantum dots are particles including or consisting of inorganic materials such as indium and cadmium, emit light on their own, and have a diameter of several nanometers or less.

By controlling the particle size of quantum dots, light of a desired color may be displayed.

The quantum dot organic LED display panel uses a blue organic LED as a light source and displays color by attaching a layer including red and green quantum dots on it or depositing a material including red and green quantum dots.

The display panel DP in an embodiment may include or consist of various other display panels.

As shown in FIG. 5, the display panel DP includes a display area DA where an image is displayed, and a non-display area PA adjacent to the display area DA.

The non-display area PA is an area where images are not displayed.

In an embodiment, the display area DA may have a square shape, and the non-display area PA may have a shape surrounding the display area DA, for example.

However, the shape of the display area DA and the non-display area PA may be relatively designed without being limited thereto.

The housing HM provides a predetermined internal space.

The display panel DP is disposed (e.g., mounted) inside the housing HM.

In addition to the display panel DP, various electronic components, such as a power supply unit, a storage device, and an audio input/output module, may be disposed (e.g., mounted) inside the housing HM.

Referring to FIG. 6, a plurality of pixels PA1, PA2, and PA3 may be formed on the substrate SUB corresponding to the display area DA of FIG. 5.

Each pixel PA1, PA2, PA3 may include a plurality of transistors and a light-emitting element connected thereto.

An encapsulation layer ENC may be disposed on the plurality of pixels PA1, PA2, PA3.

The display area DA may be protected from external air or moisture through the encapsulation layer ENC.

The encapsulation layer ENC may be integrally provided to overlap the entirety of the surface of the display area DA, and may be partially disposed on the non-display area PA.

A first color conversion unit CC1, a second color conversion unit CC2, and a transmission unit CC3 may be disposed on the encapsulation layer ENC.

The first color conversion unit CC1 overlaps with the first pixel PA1, the second color conversion unit CC2 overlaps with the second pixel PA2, and the transmission unit CC3 overlaps with the third pixel PA3.

Light emitted from the first pixel PA1 may pass through the first color conversion unit CC1 to provide red light LR.

Light emitted from the second pixel PA2 may pass through the second color conversion unit CC2 to provide green light LG.

Light emitted from the third pixel PA3 may pass through the transmission part CC3 to provide blue light LB.

Hereinafter, the cross-sectional structure of the display area DA will be illustrated with reference to FIG. 7.

The display unit DC in an embodiment includes a first substrate SUB1.

The first substrate SUB1 may include a flexible material such as plastic that may bend, fold, or roll.

The buffer layer BF may be disposed on the first substrate SUB1.

The buffer layer BF may include a silicon nitride (SiNₓ), a silicon oxide (SiOₓ), or a silicon oxynitride.

The buffer layer BF is disposed between the first substrate SUB1 and the semiconductor layer ACT, and improves the properties of polycrystalline silicon by blocking impurities from the first substrate SUB1 during the crystallization process to form polycrystalline silicon, and by flattening the first substrate SUB1, the stress of the semiconductor layer ACT formed on the buffer layer BF may be alleviated.

A semiconductor layer ACT is disposed on the buffer layer BF.

The semiconductor layer ACT may include or consist of polycrystalline silicon or an oxide semiconductor.

The semiconductor layer ACT includes a channel region C, a source region S, and a drain region D.

The source region S and drain region D are respectively disposed on opposite sides of the channel region C.

The channel region C is an intrinsic semiconductor that is not doped with impurities, and the source region S and drain region D are impurity semiconductors that are doped with conductive impurities.

The semiconductor layer ACT may include or consist of an oxide semiconductor. In this case, a protective layer may be added to protect the oxide semiconductor material, which is vulnerable to external environments such as a relatively high temperature.

A gate insulating layer GI is disposed on the semiconductor layer ACT.

The gate insulating layer GI may be a single layer or a multilayer including at least one of a silicon nitride (SiNₓ), a silicon oxide (SiOₓ), and a silicon oxynitride.

A gate electrode GE is disposed on the gate insulating layer GI. The gate electrode GE may be a multilayer stacked metal layer including any one of copper (Cu), copper alloys, aluminum (Al), aluminum alloys, molybdenum (Mo), and molybdenum alloys.

An inter-insulating layer IL1 is disposed on the gate electrode GE and the gate insulating layer GI.

The inter-insulating layer IL1 may include a silicon nitride (SiNₓ), a silicon oxide (SiOₓ), or a silicon oxynitride.

Openings exposing the source region S and drain region D are disposed in the inter-insulating layer IL1.

A source electrode SE and a drain electrode DE are disposed on the inter-insulating layer IL1.

The source electrode SE and drain electrode DE are respectively connected to the source region S and drain region D of the semiconductor layer ACT through an opening defined in the inter-insulating layer IL1.

A protective layer IL2 is disposed on the inter-insulating layer IL1, the source electrode SE, and the drain electrode DE.

The protective layer IL2 covers and flattens the inter-insulating layer IL1, the source electrode SE, and the drain electrode DE, so that the first electrode E1 may be formed on the protective layer IL2 without steps.

This protective layer IL2 may include or consist of an organic material such as polyacrylate resin or polyimide resin, or a laminated layer of an organic material and an inorganic material.

The first electrode E1 is disposed on the protective layer IL2.

The first electrode E1 is connected to the drain electrode DE through an opening in the protective layer IL2.

A driving transistor including a gate electrode GE, a semiconductor layer ACT, a source electrode SE, and a drain electrode DE is connected to the first electrode E1 to supply a driving current to the light-emitting element ED.

In addition to the driving transistor shown in FIG. 7, the display device in the illustrated embodiment includes a switching transistor (not shown) connected to the data line and transmitting a data voltage in response to the scan signal, and a switching transistor (not shown) connected to the driving transistor and driven in response to the scan signal, it may further include a compensation transistor (not shown) that compensates for the threshold voltage of the transistor.

A pixel defining layer PDL is disposed on the protective layer IL2 and the first electrode E1, and the pixel defining layer PDL may have a pixel opening that overlaps the first electrode E1 and defines a light-emitting area.

The pixel defining layer PDL may include or consist of an organic material such as a polyacrylate resin or a polyimide resin, or a silica-based inorganic material.

The pixel opening may have a planar shape substantially similar to that of the first electrode E1, and may have a diamond or octagonal shape similar to a diamond in a plan view, but is not limited thereto and may have any shape such as a square or polygon.

The light-emitting layer EML is disposed on the first electrode E1 overlapping the pixel opening.

The light-emitting layer EML may include or consist of a low-molecular organic material or a high-molecular organic material such as poly 3,4-ethylenedioxythiophene (“PEDOT”).

In addition, the light-emitting layer EML includes a hole injection layer (“HIL”), a hole transporting layer (“HTL”), an electron transporting layer (“ETL”), and an electron injection layer (“EIL”), and it may be a multilayer including one or more layers.

The emitting layer EML may be disposed mostly within the pixel opening, and may also be disposed on the side or on the pixel defining layer PDL.

The second electrode E2 is disposed on the light-emitting layer EML.

The second electrode E2 may be disposed across a plurality of pixels and may receive a common voltage through a common voltage transmitter (not shown) in the non-display area.

The first electrode E1, the light-emitting layer EML, and the second electrode E2 may form a light-emitting element ED.

In an embodiment, the light-emitting element ED may emit blue light, and in another embodiment, it may emit a combination of blue light and green light.

Here, the first electrode E1 may be an anode, which is a hole injection electrode, and the second electrode E2 may be a cathode, which is an electron injection electrode.

However, the disclosure is not necessarily limited to this, and the first electrode E1 may be a cathode and the second electrode E2 may be an anode depending on the driving method of the organic light-emitting display device.

Holes and electrons are injected into the light-emitting layer EML from the first electrode E1 and the second electrode E2, respectively, and light emission occurs when the exciton combined with the injected holes and electrons falls from the excited state to the ground state.

An encapsulation layer ENC is disposed on the second electrode E2.

The encapsulation layer ENC may seal the display layer by covering not only the top surface but also the side surfaces of the display layer including the light-emitting element ED.

Since the light-emitting element is substantially vulnerable to moisture and oxygen, the encapsulation layer ENC seals the display layer and blocks the inflow of external moisture and oxygen.

The encapsulation layer ENC may include a plurality of layers, and may be formed as a composite layer including both an inorganic layer and an organic layer, including a first inorganic layer EIL1, an organic layer EOL, and a second inorganic layer, and EIL2 may include or consist of sequentially formed triple layers.

A color conversion layer CC may be disposed on the encapsulation layer ENC.

The color conversion layer (also referred to as a color conversion unit) CC may include a partition BK1 disposed on the encapsulation layer ENC.

A first opening OP1, a second opening OP2, and a third opening OP3 that overlap the pixel opening may be defined in the partition BK1.

The sizes of the first opening OP1, the second opening OP2, and the third opening OP3 may be different or the same.

The first color conversion layer CCL1 of a red light emission area RLA may be disposed within the first opening OP1. The first color conversion layer CCL1 may convert supplied light into red. The first color conversion layer CCL1 may include red quantum dots.

The second color conversion layer CCL2 of a green light emission area GLA may be disposed within the second opening OP2. The second color conversion layer CCL2 may convert supplied light into green. The second color conversion layer CCL2 may include green quantum dots.

The transmission layer TL may overlap the third opening OP3. The transmission layer TL may be disposed in a portion corresponding to the blue light emission area BLA in the space partitioned by the partition BK1. The transmission layer TL may include a scatterer SC. The scatterer SC may include at least one of SiO₂, BaSO₄, Al₂O₃, ZnO, ZrO₂, and TiO₂.

The transmission layer TL may include a polymer resin and scatterers included in the polymer resin. In an embodiment, the transmission layer TL may include TiO_{2, for example}, but is not limited thereto.

The transmission layer TL may transmit light incident from the light-emitting element ED.

In the display panel according to this embodiment, the first color conversion layer CCL1 converts the incident light into red and emits the converted light.

Additionally, the second color conversion layer CCL2 converts the incident light into green and emits the converted light.

However, the light incident on the transmission layer TL is transmitted without color conversion.

The incident light may include blue light.

The incident light may be blue light alone or a combination of blue light and green light.

In an alternative embodiment, it may include all of blue light, green light, and red light.

The first color conversion layer CCL1 and the second color conversion layer CCL2 may be disposed on the encapsulation layer ENC. The first color conversion layer CCL1 and the second color conversion layer CCL2 may contact the encapsulation layer ENC.

In the embodiment of FIG. 7, the first layer described in FIG. 1 may be an encapsulation layer ENC, and in particular, may be a second inorganic layer EIL2.

The interface between the first color conversion layer CCL1 and the encapsulation layer ENC, and the interface between the second color conversion layer CCL2 and the encapsulation layer ENC may include the first region and the second region as referred to in FIGS. 1 to 4.

The information about the first layer L1 previously described with reference to FIGS. 1 to 4 may be applied to the encapsulation layer ENC, and for the bonding relationship between one side of the encapsulation layer ENC and the first color conversion layer CCL1, the content previously described with reference to FIGS. 1 to 4 may be applied.

The contents are briefly explained below.

As described above, the interface between the first color conversion layer CCL1 and the encapsulation layer ENC, and the interface between the second color conversion layer CCL2 and the encapsulation layer ENC, have the first region having hydrophilic and the second region having hydrophobicity. The first region and the second region may be randomly arranged.

The ratio of the area occupied by the first region to the area occupied by the second region may be 4:6 to 6:4, e.g., 5:5.

The first region may be a region surface-treated with a first compound including an acrylate group.

Specifically, the first region may be a region surface-treated with a first compound represented by Formula 1 and Formula 2 below.

The first region may exhibit hydrophilicity due to the first compound represented by Formula 1 to Formula 2.

Specifically, the first compound represented by Formula 1 and Formula 2 may be bound to a surface of the second inorganic layer EIL2.

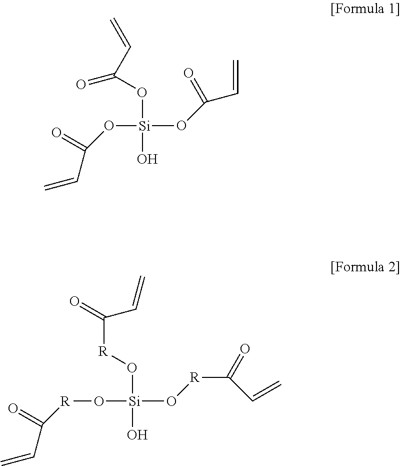

In Formula 2, R denotes an alkyl group having 1 carbon atom to 20 carbon atoms.

The second region may be a region whose surface has been treated with a second compound.

The second region may be a region surface-treated with a second compound represented by the following Formula 3.

The second region may exhibit hydrophobicity due to the second compound represented by Formula 3.

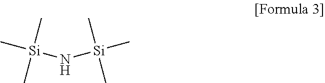

The first color conversion layer CCL1 and the second color conversion layer CCL2 in an embodiment may be formed on the encapsulation layer ENC that has undergone surface treatment.

The color conversion layers CCL1 and CCL2 include or consist of a photosensitive resin composition and may be formed through a photocuring process, an exposure process, and a development process.

The photosensitive resin composition for forming the color conversion layer CCL1, CCL2 in an embodiment may include a photocuring group, and the photocuring group may be an acrylate-based photocuring group.

The acrylate-based photocuring group may combine with the first compound represented by Formula 1 and Formula 2 formed in the first region during the exposure process.

The first color conversion layer CCL1 and the second color conversion layer CCL2 in an embodiment may be covalently bonded to a portion of the encapsulation layer ENC, particularly the first region.

The second region is hydrophobic, and the color conversion layers CCL1 and CCL2 disposed on the second region are not directly bonded to the second region R2.

Now, the quantum dots included in each of the first color conversion layer CCL1 and the second color conversion layer CCL2 will be described in detail below.

In this specification, quantum dots (hereinafter also referred to as semiconductor nanocrystals) include group II-VI compounds, group III-V compounds, group IV-VI compounds, group IV elements or compounds, group I-III-VI compounds, and group II-III compounds, and it may include a group-VI compound, a group I-II-IV-VI compound, or any combinations thereof.

The II-VI group compounds include binary compounds including CdSe, CdTe, ZnS, ZnSe, ZnTe, ZnO, HgS, HgSe, HgTe, MgSe, MgS, or any combinations thereof; AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or any combinations thereof, and a military tri-element compound selected therefrom; and a tetraelement compound including HgZnTeS, CdZnSeS, CdZnSeTe, CdZnSTe, CdHgSeS, CdHgSeTe, CdHgSTe, HgZnSeS, HgZnSeTe, HgZnSTe, or any combinations thereof.

The Group II-VI compound may further include a Group III metal.

The III-V group compounds include binary compounds including GaN, GaP, GaAs, GaSb, AlN, AlP, AlAs, AlSb, InN, InP, InAs, InSb, or any combinations thereof; A ternary compound including GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, or any combinations thereof; and a quaternary compound including GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, or any combinations thereof.

The group III-V compound may further include a group II metal (e.g., InZnP).

The IV-VI group compounds include binary compounds including SnS, SnSe, SnTe, PbS, PbSe, PbTe, or any combinations thereof; a ternary compound including SnSeS, SnSeTe, SnSTe, PbSeS, PbSeTe, PbSTe, SnPbS, SnPbSe, SnPbTe, or any combinations thereof; and a quaternary element including SnPbSSe, SnPbSeTe, SnPbSTe, or any combinations thereof.

The Group IV element or compound is a monoelement compound including Si, Ge, or a combination thereof; and a binary compound including SiC, SiGe, or a combination thereof, but is not limited thereto.

In embodiments, the Group I-III-VI compounds include, but are not limited to, CuInSe2, CuInS2, CuInGaSe, and CuInGaS.

In embodiments, the Group I-II-IV-VI compounds include, but are not limited to, CuZnSnSe and CuZnSnS.

The Group IV element or compound is a single element including Si, Ge, or a combination thereof; and a binary compound including SiC, SiGe, or a combination thereof.

The group II-III-VI compounds include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, or any combinations thereof, but is not limited thereto.

The group I-II-group IV-VI compound may include or consist of CuZnSnSe, CuZnSnS, or a combination thereof, but is not limited thereto.

In an embodiment, the quantum dots may not include cadmium.

Quantum dots may include semiconductor nanocrystals based on group III-V compounds including indium and phosphorus.

The group III-V compound may further include zinc.

Quantum dots may include semiconductor nanocrystals based on II-VI compounds including chalcogen elements (e.g., sulfur, selenium, tellurium, or combinations thereof) and zinc.

In quantum dots, the above-mentioned di-element compound, tri-element compound, and/or quaternary compound may exist in the particle at a uniform concentration, or may exist in the same particle with the concentration distribution partially divided into different states.

Additionally, one quantum dot may have a core/shell structure surrounding other quantum dots.

The interface between the core and the shell may have a concentration gradient in which the concentration of elements in the shell decreases toward the center.

In some embodiments, quantum dots may have a core-shell structure including a core including the above-described nanocrystals and a shell surrounding the core.

The shell of the quantum dot may serve as a protective layer to maintain semiconductor properties by preventing chemical denaturation of the core and/or as a charging layer to impart electrophoretic properties to the quantum dot.

The shell may be single- or multi-layered.

The interface between the core and the shell may have a concentration gradient in which the concentration of elements in the shell decreases toward the center.

In embodiments, the shell of the quantum dot include metal or non-metal oxides, semiconductor compounds, or combinations thereof.

In an embodiment, the oxide of the metal or non-metal is a binary compound such as SiO2, Al2O3, TiO2, ZnO, MnO, Mn2O3, Mn3O4, CuO, FeO, Fe2O3, Fe3O4, CoO, Co3O4, NiO, or MgAl2O4, CoFe2O4, NiFe2O4, CoMn2O4, etc., or any combinations thereof, for example, but the invention is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, the invention is not limited thereto.

The interface between the core and the shell may have a concentration gradient in which the concentration of elements in the shell decreases toward the center.

Additionally, the semiconductor nanocrystal may have a structure including a single semiconductor nanocrystal core and a multi-layered shell surrounding it.

In an embodiment, the multilayer shell may have two or more layers, such as two, three, four, five, or more layers.

The two adjacent layers of the shell may have a single composition or different compositions.

In a multilayer shell, each layer may have a composition that changes along the radius.

Quantum dots may have a full width at half maximum (“FWHM”) of the emission wavelength spectrum of about 45 nanometers (nm) or less, preferably about 40 nm or less, more preferably about 30 nm or less, and within this range, color purity or color reproducibility may be improved.

Additionally, since the light emitted through these quantum dots is emitted in all directions, the optical viewing angle may be improved.

The quantum dots may have different energy band gaps between the shell material and the core material.

In an embodiment, the energy band gap of the shell material may be larger than that of the core material, for example.

In other embodiments, the energy band gap of the shell material may be smaller than that of the core material.

The quantum dots may have a multi-layered shell.

In a multi-layered shell, the energy band gap of the outer layer may be larger than that of the inner layer (i.e., the layer close to the core).

In a multilayer shell, the energy band gap of the outer layer may be smaller than that of the inner layer.

Quantum dots may control absorption/emission wavelengths by adjusting their composition and size.

The maximum emission peak wavelength of the quantum dot may range from ultraviolet to infrared wavelengths or longer.

Quantum dots may have a quantum efficiency of at least about 10%, such as at least about 30%, at least about 50%, at least about 60%, at least about 70%, at least about 90%, or even at least 100%.

Quantum dots may have a relatively narrow spectrum.

The quantum dots may have a full width at half maximum of the emission wavelength spectrum of about 50 nm or less, such as about 45 nm or less, about 40 nm or less, or about 30 nm or less, for example.

The quantum dots may have a particle size of about 1 nm or more and about 100 nm or less.

The size of a particle refers to the diameter of the particle or the diameter converted by assuming a spherical shape from a two-dimensional image obtained by transmission electron microscope analysis.

The quantum dots may have a size of about 1 nm to about 20 nm, e.g., 2 nm or more, 3 nm or more, or 4 nm or more and 50 nm or less, 40 nm or less, 30 nm or less, 20 nm or less, 15 nm or less, e.g., 10 nm or less.

The shape of the quantum dot is not particularly limited.

In an embodiment, the shape of the quantum dot may include, but is not limited to, a sphere, polyhedron, pyramid, multipod, square, cuboid, nanotube, nanorod, nanowire, nanosheet, or any combinations thereof, for example.

Quantum dots are commercially available or may be appropriately synthesized.

The particle size of quantum dots may be controlled relatively freely during colloid synthesis, and the particle size may also be adjusted uniformly.

Quantum dots may include organic ligands (e.g., having hydrophobic and/or hydrophilic moieties).

The organic ligand residue may be bound to the surface of the quantum dot.

The organic ligand includes RCOOH, RNH₂, R₂NH, R₃N, RSH, R₃PO, R₃P, ROH, RCOOR, RPO(OH)₂, RHPOOH, R₂POOH, or any combinations thereof, where R is each independently substituted or unsubstituted alkyl of C3 to C40 (e.g., C5 or more and C24 or less), substituted or unsubstituted alkenyl, a substituted or unsubstituted aliphatic hydrocarbon group of C3 to C40, a substituted or unsubstituted aryl group of C6 to C40, or it may be a substituted or unsubstituted aromatic hydrocarbon group of C6 to C40 (e.g., C6 or more and C20 or less), or any combinations thereof.

In embodiments, the organic ligand include thiol compounds such as methane thiol, ethane thiol, propane thiol, butane thiol, pentane thiol, hexane thiol, octane thiol, dodecane thiol, hexadecane thiol, octadecane thiol, and benzyl thiol; methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, amines such as tributylamine, trioctylamine, etc.; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, trioctyl phosphine, etc.; phosphines such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and trioctyl phosphine oxide, a compound or its oxide compound; diphenyl phosphine, triphenyl phosphine compounds or their oxide compounds; C5 to C20 alkyl phosphinic acids, C5 to C20 alkyl phosphonic acids such as hexylphosphinic acid, octylphosphinic acid, dodecanephosphinic acid, tetradecanephosphinic acid, hexadecanephosphinic acid, and octadecanephosphinic acid; but are not limited thereto.

Quantum dots may include hydrophobic organic ligands alone or in a combination of one or more types.

The hydrophobic organic ligand may not include or consist of a photopolymerizable residue (e.g., an acrylate group, a methacrylate group, etc.).

The first insulating layer IL3 may be disposed on the partition BK1, the first color conversion layer CCL1, the second color conversion layer CCL2, and the transmission layer TL.

The first insulating layer IL3 may cover the partition BK1, the first color conversion layer CCL1, the second color conversion layer CCL2, and the transmission layer TL.

The first insulating layer IL3 may include at least one of a silicon nitride, a silicon oxide, and a silicon nitride.

In an embodiment, the first insulating layer IL3 may be omitted.

The filling layer FL may be disposed on the first insulating layer IL3.

The filling layer FL may combine components disposed on the first substrate SUB1 and components disposed on the second substrate SUB2.

One display panel may be formed through the filling layer FL.

A second insulating layer IL4 may be disposed on the filling layer FL.

The second insulating layer IL4 may include, e.g., a silicon nitride (SiNₓ), a silicon oxide (SiOₓ), or a silicon oxynitride.

Depending on the embodiment, the second insulating layer IL4 may be omitted.

A third insulating layer IL5 may be disposed on the second insulating layer IL4.

In an embodiment, the third insulating layer IL5 may include an organic material or an inorganic material such as a silicon nitride (SiNₓ), a silicon oxide (SiOₓ), or a silicon oxynitride, for example.

The color conversion unit CC includes a first color filter CF1, a second color filter CF2, and a third color filter CF3 disposed between the second substrate SUB2 and the display unit DC.

The first color filter CF1 may overlap the transmission layer TL.

The first color filter CF1 may transmit blue light that has passed through the transmission layer TL and absorb light of the remaining wavelengths, thereby increasing the purity of blue light emitted to the outside of the display device.

The second color filter CF2 may overlap the first color conversion layer CCL1.

The second color filter CF2 may transmit red light that has passed through the first color conversion layer CCL1 and absorb light of the remaining wavelengths, thereby increasing the purity of red light emitted to the outside of the display device.

The third color filter CF3 may overlap the second color conversion layer CCL2.

The third color filter CF3 may transmit green light that has passed through the second color conversion layer CCL2 and absorb light of the remaining wavelengths, thereby increasing the purity of green light emitted to the outside of the display device.

At least two of the third color filter CF3, second color filter CF2, and first color filter CF1 may overlap in a non-emission area NLA1 and serve as a light-blocking member.

The non-emission area NLA1 may overlap the pixel defining layer PDL of the display unit DC and the partition BK1 of the color conversion unit CC.

The color conversion layers CCL1 and CCL2 in an embodiment are formed in a stable pattern on the encapsulation layer ENC and are attached with appropriate adhesive force, so the reliability of the display device may be improved.

The disclosure has described an embodiment in which the color conversion layer contacts the encapsulation layer, but it is not limited to this, and embodiments in which the color conversion layer is formed on a glass substrate or an organic insulating layer and the above contents are applied are of course also possible.

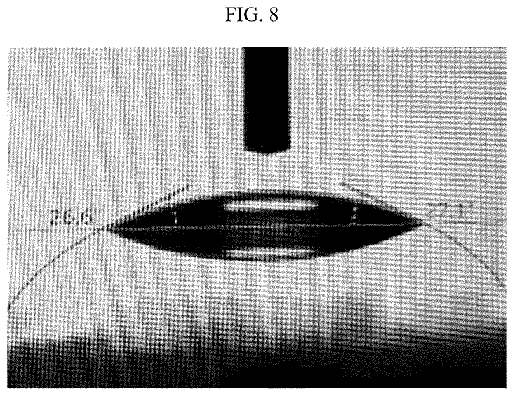

Hereinafter, examples and comparative examples will be illustrated with reference to FIGS. 8 to 15.

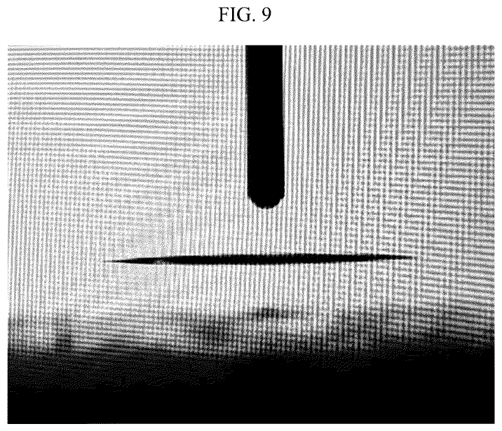

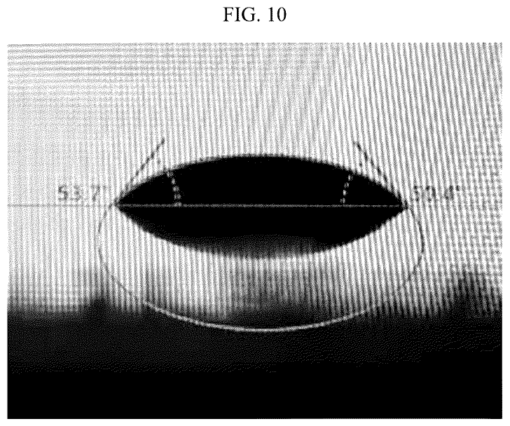

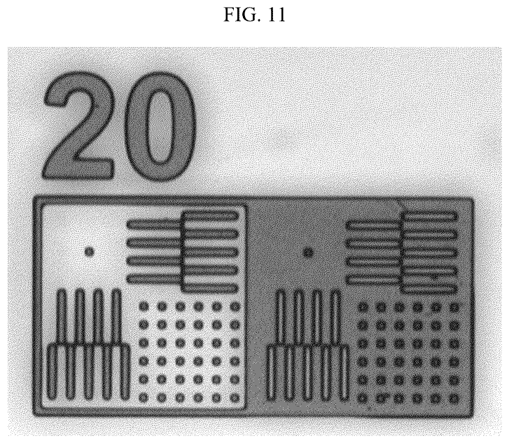

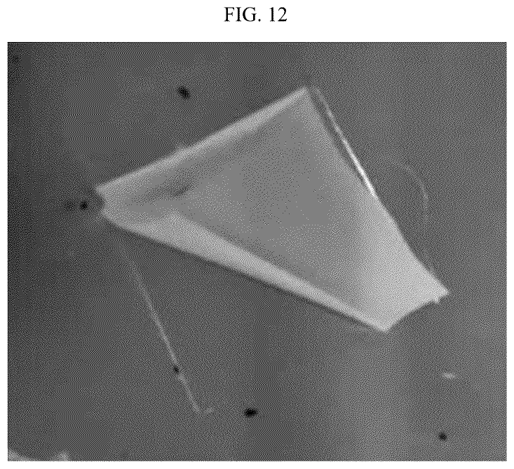

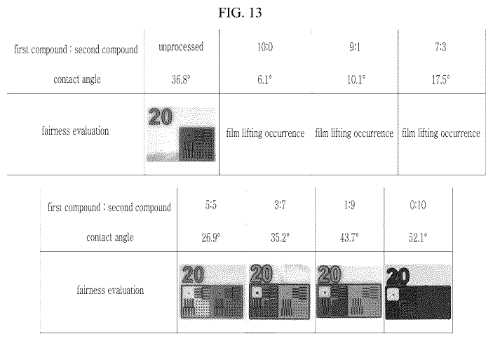

FIG. 8 is an image showing an embodiment of the contact angle of the first layer surface-treated, FIGS. 9 and 10 are images showing a comparative example of the contact angle of the first layer surface-treated, FIG. 11 is an image showing an embodiment of the contact angle of the first layer surface-treated, FIG. 12 is an image of comparative example patterned with a photosensitive resin composition on the first layer surface-treated, and FIGS. 13 to 15 are embodiments and a table showing images of comparative examples.

First, FIG. 8 is an image showing an embodiment of the contact angle when the surface of the first layer has both hydrophobicity and hydrophilicity.

After surface treating the first layer with a 5:5 mixture of the first compound providing hydrophilicity and the second compound providing hydrophobicity, the contact angle was checked and found to be about 26.9 degrees.

As shown in FIG. 9, when the first layer was surface treated with the first compound to have only hydrophilicity, a contact angle of about 6.1 degrees was shown.

As shown in FIG. 10, when the first layer was surface treated with a second compound to have only hydrophobicity, a contact angle of approximately 52.1 degrees was obtained.

Additionally, as a result of performing a patterning process using the photosensitive resin composition on the same first layer, it was confirmed that the patterning process was performed in a clear form without residue or tearing, as shown in FIG. 11.

This is because when patterning using a photosensitive resin composition including a photocurable group on the first layer that provides both hydrophilicity and hydrophobicity, the photocurable group and the hydrophilic region form a covalent bond, thereby improving the adhesion of the exposed area.

As shown in FIG. 12, when the surface of the first layer was treated to have only hydrophilicity, it was confirmed that the photosensitive resin composition was lifted during the development process and patterning was impossible.

Referring to FIG. 13, when the mixing ratio of the first compound that makes the surface of the first layer hydrophilic to the second compound that makes the surface of the first layer hydrophobic is changed from 10:0 to 0:10, the contact angle was examined and a fairness evaluation was conducted.

It was confirmed that as the mixing ratio of the second compound to the first compound increases, the hydrophobicity of the surface of the first layer increases, and thus the contact angle increases.

Additionally, it was confirmed that as the mixing ratio of the first compound to the second compound increased, patterning of the photosensitive resin composition formed on the first layer became impossible.

This was confirmed to be lifting due to the repulsive force between the first layer and the photosensitive resin composition.

However, it was confirmed that when the mixing ratio of the first compound to the second compound was greater than 7:3 and less than 3:7, patterning proceeded at an appropriate level without layer lifting of the photosensitive resin composition.

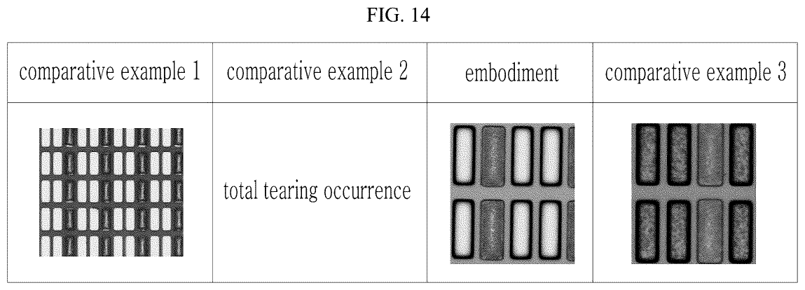

Also, referring to FIG. 14, Comparative Example 1 is an image in which a photosensitive resin composition was applied to the first layer without any additional surface treatment and a patterning process was performed.

When no separate surface treatment was performed, it was confirmed that the patterned color conversion layer was lifted as the patterning process was performed.

Comparative Example 2 is a case where the surface of the first layer was hydrophilic treated using only the first compound, and it was confirmed that the patterning process could not be performed and overall tearing occurred.

Additionally, Comparative Example 3 is a case where the surface of the first layer was hydrophobically treated using only the second compound.

After performing the patterning process, it was confirmed that considerable residue remained in other areas.

In the case of the example in which the first layer was surface treated by mixing the first compound and the second compound in a ratio of 5:5, it was confirmed that the patterning process was performed without residue and that adhesion was excellent.

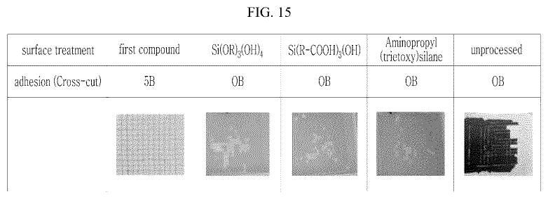

Referring to FIG. 15, in addition to surface treatment with the first compound, surface treatment of the first layer with another siloxane-based compound was performed to evaluate the adhesion of the photosensitive resin composition.

According to FIG. 15, it was confirmed that the adhesion was not improved at all when the surface of the first layer was treated with other siloxane-based compounds.

That is, it was confirmed that the adhesion between the first layer and the exposed photosensitive resin composition was improved only when the surface was treated with the first compound.

While the alkoxy group, carboxyl group, and amine group were not bonded to the photosensitive resin composition, it was confirmed that the adhesion was improved by covalent bonding between the first layer surface-treated with the first compound and the exposed photosensitive resin composition.

Although the embodiments of the invention have been described in detail above, the scope of the invention is not limited thereto, and various modifications and improvements made by those skilled in the art using the basic concepts of the invention defined in the following claims are also possible.

What is claimed is:

1. A display device comprising:
a substrate;
a transistor disposed on the substrate;
a light-emitting element electrically connected to the transistor;
a first layer disposed on the light-emitting element, the first layer comprising:
a surface including:
a first region having hydrophilicity, and
a second region having hydrophobicity, and
a color conversion layer in contact with the first layer and including quantum dots.

2. The display device of claim 1, wherein
the first region includes an acrylate group.

3. The display device of claim 1, wherein
the second region includes hexamethyldisilazane.

4. The display device of claim 1, wherein
the first region and the second region are randomly arranged.

5. The display device of claim 1, wherein
an area ratio of the first region to an area of the second region is 4:6 to 6:4.

6. The display device of claim 1, wherein
the color conversion layer is covalently bonded to the first region.

7. The display device of claim 6, wherein
the color conversion layer comprises an acrylate-based photocuring group.

8. The display device of claim 7, wherein
the acrylate-based photocurer forms a covalent bond with the first region.

9. The display device of claim 1, wherein
the light-emitting element emits blue light.

10. The display device of claim 1, wherein
the color conversion layer comprises
a first color conversion layer including red quantum dots, and
a second color conversion layer including green quantum dots.

11. A display device comprising:
a substrate;
a transistor disposed on the substrate;
a light-emitting element electrically connected to the transistor;
a first layer disposed on the light-emitting element; and
a color conversion layer in contact with the first layer,
wherein an interface between the first layer and the color conversion layer includes a first region where the first layer and the color conversion layer form a covalent bond.

12. The display device of claim 11, wherein
the interface between the first layer and the color conversion layer further includes a second region in which the first layer and the color conversion layer do not form a covalent bond, and
the first region and the second region are randomly disposed.

13. The display device of claim 11, comprising
the first layer is at least one of a glass substrate, an organic insulating layer, and an inorganic insulating layer.

14. The display device of claim 11, wherein
the first region is surface-treated with a first compound represented by following Formula 1 or Formula 2: 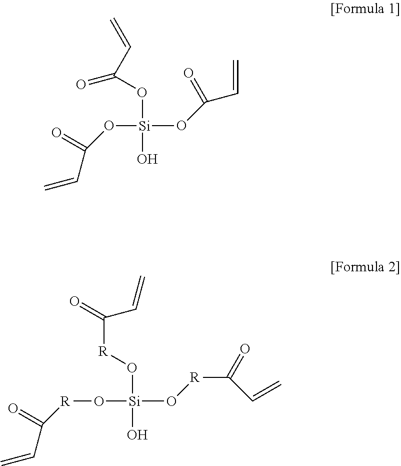
wherein, in Formula 2, R denotes an alkyl group having 1 carbon atom to 20 carbon atoms.

15. The display device of claim 12, wherein
the second region is surface-treated with a second compound represented by following Formula 3:

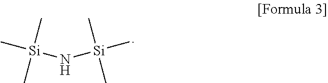

16. The display device of claim 12, wherein
a ratio of an area of the first region to an area of the second region is 4:6 to 6:4.

17. The display device of claim 16, wherein
the color conversion layer comprises an acrylate-based photocuring group.

18. The display device of claim 17, wherein
the acrylate-based photocurer forms a covalent bond with the first region.

19. The display device of claim 11, wherein
the light-emitting element emits blue light.

20. The display device of claim 11, wherein
the color conversion layer comprises
a first color conversion layer including red quantum dots, and
a second color conversion layer including green quantum dots.
